(19) United States
(12) Patent Application Publication
(10) Pub. No.: US 2007/0114060 A1
(43) Pub. Date: May 24, 2007

(54) EMC gasket with built-in chassis retention

(75) Inventors: Dennis R. Barringer, Wallkill, NY (US); Mark A. Marnell, Kingston, NY (US); Prabjit Singh, Poughkeepsie, NY (US); Ivan O. Svenson, Hyde Park, NY (US)

Correspondence Address: Lily Neff;IBM Corporation - MS P386, 2455 South Road, Poughkeepsie, NY, 12601, US

(73) Assignee: International Business Machines Corporation, Armonk, NY (US)

(21) Appl. No.: 11/284,744

(22) Filed: Nov. 22, 2005

(51) Int. Cl. H05K 9/00

(52) U.S. Cl. 174/354; 174/355

(57) ABSTRACT

A method and associated apparatus for providing an electromagnetic seal in electrical enclosure of a device. The apparatus comprising of an electromagnetic gasket formed of a thin conductive material, having a first end and an opposing end. The apparatus also includes a conductive chassis disposed in the electrical enclosure and having protrusions for securing at least one end of the gasket. The other end of the gasket is also secured to the chassis in a manner to provide facility of compression.

### CROSS-REFERENCE TO RELATED APPLICATIONS

This application contains subject matter which is related to the subject matter of the following co-pending applications, filed on the same day, which is assigned to the same assignee as this application, International Business Machines Corporation of Armonk, New York. The application listed below is hereby incorporated herein by reference in its entirety the following U.S. Pat. No. 6,794,571

### BACKGROUND OF THE INVENTION

1. Field of the Invention

The present invention relates to an electromagnetic compatibility (EMC) sealing apparatus and related method; and more particularly to a dynamic EMC sealing apparatus and method for an electrical enclosure used in computing system environments.

2. Description of Background

It is an industry goal to continuously increase the number of electronic components inside an electronic device. This goal is driven by several key and important reasons. The first and more obvious one is for the convenience of compactness. Compactness allows for selective fabrication of smaller and lighter devices that are more attractive to the consumer. Some of the reasons for such appeal stem from a desire for easier transportation, shipping, installation and storage of such devices. In other instances, when compactness per se is not a driving factor, providing the same number of devices in only a fraction of available footprint allows the remaining space to be filled with more components which will increase system performance and speed. In addition, compactness also allows many of the circuits to operate at higher frequencies and at higher speeds due to shorter electrical distances in these devices. Unfortunately, despite many of the advantages associated with this industry goal, there are several important challenges that have to be overcome by the designers of these systems.

One area where the challenges and advantages provided by such compact densities is increased is in the computer industry. The reliance of many businesses on computers and computer networks in recent years, demands an ever increasing need to provide fast and accurate systems in the smallest and lightest allowable footprint. In a computing environment, whether comprising of a simple personal computer, or a complex system comprising of a number of computers in processing communication with one another, a plurality of printed circuit boards and cards are provided that house many electronic components and even devices.

A particularly challenging area for the designers of these systems is the issue of resolving electromagnetic interference (EMI). As the number of components are increased, electromagnetic leakage concerns continue to grow. This is because every electronic device, emits some form of electromagnetic radiation. If unresolved, EMI can affect both system performance, data integrity and speed. Obviously, in larger system environments, the increased number of components that are stored in close proximity to one another, greatly increases the EMI concerns. This is because while such effects can be tolerated when few devices and components exist, the increasing number of components and devices can seriously impact system integrity and performance. This problem is further exacerbated by the improvement in semiconductor devices which allow them to operate at higher speeds, generally causing emission in higher frequency bands where interference is more likely to occur.

Prior art attempts have been made to minimize the interference problem. Electromagnetic compatibility (EMC) requires that emissions from a given device be reduced by shielding or other similar means. Such shieldings are designed not only to reduce emissions from the device itself, but also to reduce sensitivity of the device to external fields such as fields from other devices. One type of such EMI shieldings are EMI gaskets.

In recent designs, it is necessary to use a metallic type of electromagnetic gaskets to provide better conduction with an electrical enclosure in which the printed circuit boards or cards are engaged. A common problem with such gaskets, however, are that they are easily damaged as a result of deflection of gasket during insertion or removal of printed circuit cards that reside in the computing system environment during mundane activities such as during servicing calls. Once the gasket has been damaged, not only does it no longer provides EMI protection for the device but it may even pose a threat for a potential short.

Related patent U.S. Pat. No. 6,794,571 by Barringer et al. (hereinafter Barringer patent), owned by the same assignee, International Business Machines Corporation, and coauthored by at least some of the inventors of this application, provided a method and apparatus for providing an electromagnetic conduction seal in a device disposed within an electrical enclosure including a metal EMC gasket.

Related patent solved the prior art problem of minimizing damages to such gaskets. This is especially true with EMC metal gaskets that have a spring design. In such gaskets, often one end of the gasket is only attached to a chassis with the other end left hanging without any retention. This other end is especially vulnerable to being damaged by being for example caught in some other object. The Barringer patent introduced a retention mechanism that provided for a lock strip to be fixed to the device. The gasket in that patent was secured to a device that provided limits of deflection of an intermediate portion to the gasket using an external part.

While the Barringer patent solves many of the prior art problems, it is desirable to introduce a mechanism that can be fabricated at the same time as the chassis itself. In addition, providing a mechanism that does not provide a lock strip can allow the gasket to be used in environments where the installation or later exposure to high temperatures (such as caused by heat dissipation issues) can cause the lock strip to come unhinged. An example would be where glue is used and heat or installation can cause the glue to come undone.

### SUMMARY OF THE INVENTION

The shortcomings of the prior art are overcome and additional advantages are provided through the method and associated apparatus for providing an electromagnetic seal in electrical enclosure of a device. The apparatus comprising of an electromagnetic gasket formed of a thin conductive material, having a first end and an opposing end. The apparatus also includes a conductive chassis disposed in the electrical enclosure and having protrusions for securing at least one end of the gasket. The other end of the gasket is also secured to the chassis in a manner to provide facility of compression. The other end of the gasket is secured to the chassis either through adhesive bonding, through use of other alternate protrusions or another similar manner.

Additional features and advantages are realized through the techniques of the present invention. Other embodiments and aspects of the invention are described in detail herein and are considered a part of the claimed invention. For a better understanding of the invention with advantages and features, refer to the description and to the drawings

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a perspective docking cassette inside which the gasket of present embodiment will be disposed in one embodiment;

FIG. 2 is an isometric view of the docking cassette of FIG. 1 with its cover removed;

FIG. 3 is an isometric view of the docking cassette of FIG. 1 and 2 with the printed board card removed;

FIG. 4 is a top down embodiment of the present invention showing gasket and chassis assembly in the docking cassette of FIG. 1;

FIG. 5 is a cross sectional illustration of the gasket as per one embodiment of the present invention; and

FIG. 6 is a perspective illustration showing better gasket details.

### DESCRIPTION OF THE INVENTION

The embodiments provided in conjunction with the following figures provide for a preferred embodiment where the EMC gasket of present embodiment is disposed in a computing environment. It should be noted that this embodiment is only provided for ease of understanding and the teaching of the present invention can equally apply to other devices and in conjunction with other electrical disclosures.

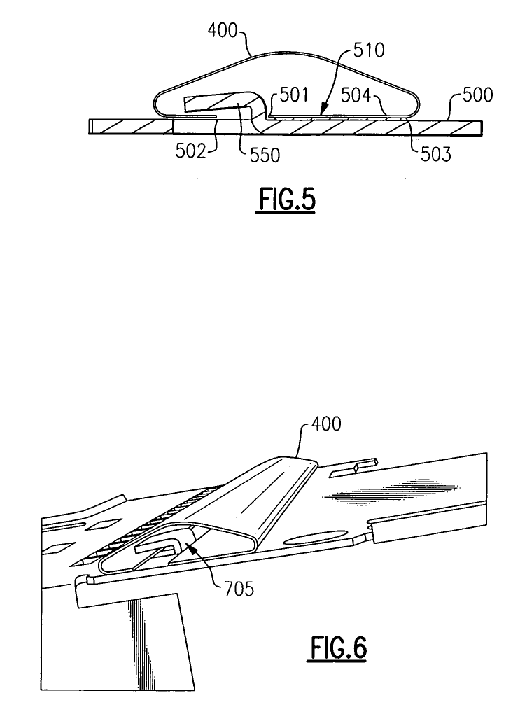

FIGS. 5 provides a cross sectional illustration of one embodiment of the present invention. The illustration of FIG. 5, provides for an EMC gasket with a unique retain feature that can be fabricated at the same time and the same material of the gasket and does not require additional adhesives and other such components. Related U.S. Pat. No. 6,794,571, while solving many of the problems that were associated with prior art proposed a solution with a retainable feature that required extra mounting steps, such as adhesion, and that were provided of additional materials, such as plastic, that had to be fabricated separately and then disposed individually adding an yet an additional fabricating step as per an exemplary embodiment.

Before discussing the unique features comprising the EMC gasket of the present invention, FIGS. 1 through 4 will be discussed so as to provide a general understanding of how the gasket of present invention will be mounted and used in conjunction with other components of a computing environment.

FIG. 1 provides for a perspective view of a docking cassette which will be used in conjunction with the gasket of the present invention. The illustration of FIG. 1, provides for a docking apparatus 1 for mounting a printed circuit board (not illustrated in this figure). The docking apparatus provides structural support to the printed circuit board. The illustrated docking apparatus of FIG. 1 is shown with its cover, referenced as 10, in mounted position though cover opening components 46. The cover 10 is disposed over the cassette housing 32. Printed circuit board connector 42 is disposed to one side of the housing 32 as illustrated. Cable connectors 44 are also illustrated that provide electrical and electronic connection between the docking apparatus and other such components.

Elements referenced as 24 and 26 in FIG. 1 respectively can be called a first and second protruding components, not to be mistaken with the chassis protruding elements as will be later discussed. These components are preferably provided and used to secure the docking apparatus to a main board of a computer as will be discussed in conjunction with later figures. A housing bezel 6 is also provided that houses a chassis assembly 140, over which the EMC gasket will be eventually be mounted as will be further discussed below.

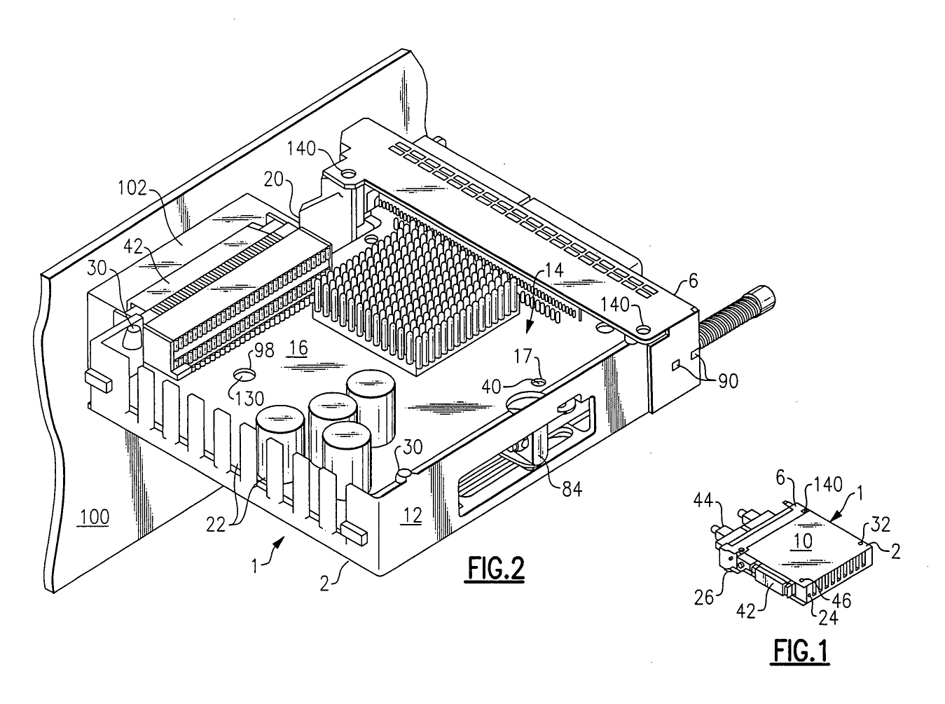

FIG. 2 provides for an isometric view illustration of the embodiment of FIG. 1. In FIG. 2, the cover 10 is removed to provide an illustration of some of the components that are disposed inside of the docking assembly 1.

In addition to the removal of the cover 10, the illustration of FIG. 2 provides for the addition of a computer main board 100 that is engaged in this depiction with the docking apparatus 1.

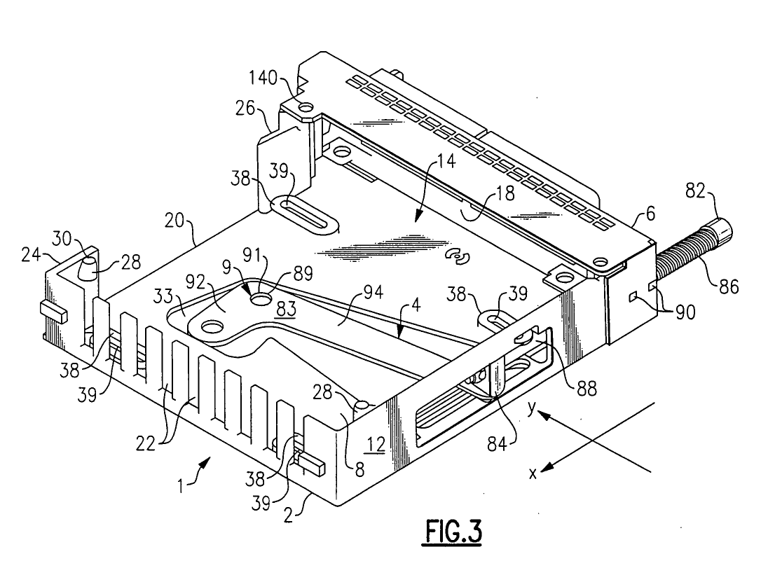

The removal of the cover 10 provides for a view of cavity 14 and walls 12. Referring back to FIG. 1 and viewing it now in conjunction with FIG. 2, it should be noted that housing cover 10 preferably includes at least one cover opening disposed as to allow communication with mounting structures, not visible in FIG. 1 but shown in FIG. 3 and referenced as 28 (visible in FIG. 3) when housing cover 10 is associated with housing wall 12. The housing cover 10 may be movably or non-movably associated with housing base 8 (also only visible in FIG. 3) and/or housing wall 12 using any mounting device or method suitable to the desired end purpose.

The components 24 and 26 as discussed in FIG. 1, can be disposed anywhere on the cassette housing 2 but in this embodiment are shown to be disposed on the housing wall 12 and are placed to lockingly engage and disengage the main board 100 with the docking apparatus 1 though the respective connector 102. Housing wall also includes a cavity 30 for receiving the mounting apparatus 32 of FIG. 1, which is not limited to but can include a screw.

The housing wall 12 also preferably includes other elements such as a cable opening 18 (shown in FIG. 3), a printed circuit board connector opening 20 and a plurality of vent openings 22.

The printed circuit board 16 is disposed inside the cavity 14 of the docking apparatus 1. In the example of FIG. 2, the printed circuit board 16 is disposed in the cavity 14 by the help of printed circuit board mounting mechanism 40 which may include a screw, a pin, or other suitable mounting mechanisms as known by those skilled in the art that are threaded for example through a printed circuit board hole 17.

In FIG. 2, part of a clevis 84 is also illustrated. In order to fully understand the purpose of the clevis 84 and how the printed circuit board 16 is linked to the docking apparatus 1, a different view needs to be provided. FIG. 3 provides such a perspective view.

In the isometric view of FIG. 3, the printed circuit board 16 is removed. The removal of printed circuit board 16, reveal a linkage mechanism 4 and housing base 8. The housing base 8 and the walls 12 are non-movably associated but are disposed as illustrated in a manner as to provide for the movable printed circuit board 16. The housing base 8 includes a linkage mounting receptacle 9 for receiving the linkage mechanism 4, as illustrated. The housing base also includes a linkage cavity 33 and four mounting devices 38 for movably holding the printed circuit board mechanism 40 to engage printed circuit board 16 of FIG. 2. The mounting device 38 preferably also includes a device opening 39 for slidingly containing printed circuit board mechanism 40 (which can include but is no limited to a screw or a pin).

The linkage mechanism includes linkage arm 83 and clevis 84 which can be pivotally coupled to the linkage arm 83 and configured to receive a shaft 88 at one end, while an opposing end includes a thread 86 engaged with an operably fixed nut (not shown) secured to either housing 2 and or housing bezel 6. In one embodiment, linkage mechanism 4 can be operably mounted within housing cavity 14 via a complimentary configured aperture 89 for receiving linkage mounting screw 91 allowing pivotal movement of linkage arm 83 about screw 91 or with any other suitable mounting device as known to those skilled in the art, including but not limited to a clip. Furthermore, linkage mechanism 4 is operably mounted within housing cavity 14 via the nut operably secured to housing bezel 6 and associated with thread 86.

Linkage arm 83 include first and second linkage arms 92 and 94 respectively substantially extending from aperture 89 and preferably perpendicular to one another. First link arm can also include an aperture provided for operable connection with corresponding aperture 98 shown and aligned therewith so as to connect printed circuit board 16 to first link arm 92 (also see FIG. 2). In this way, when linkage arm 83 pivots about screw 91, printed circuit board connector 42 (FIG. 1) electrically engages and disengages with the respective connector 102 in board 100 (FIG. 2). Second link arm 94 includes a second aperture proximate an end thereof for pivotally coupling with clevis 84. The length of arm 94 is preferably several times that of arm 92 in order to provide a mechanical advantage.

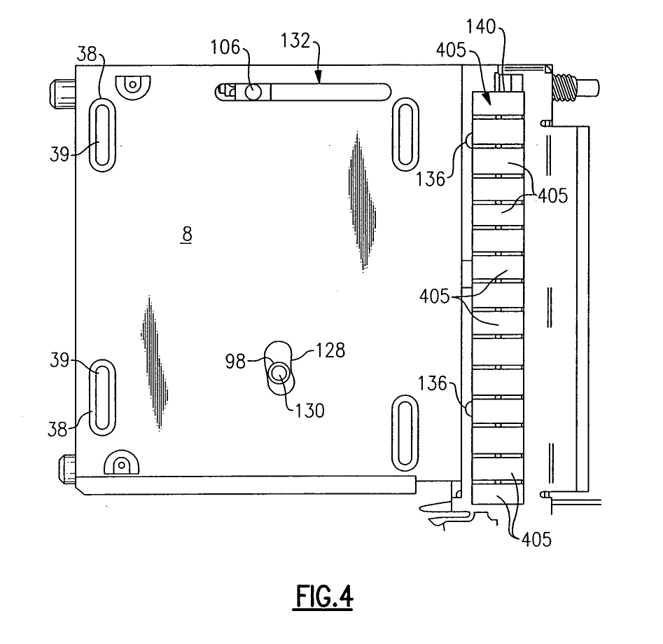

FIG. 4 provides a top down illustration of one embodiment of present invention. The purpose of providing the illustration of FIG. 4 is to focus on the gasket 400 alone. In this regard, other components that may have been already discussed are will no the discussed here as not to obscure the discussion of gasket 400. Gasket 400 is placed over the chassis assembly 140 as illustrated. In a preferred embodiment, the gasket is adhesively bonded to the chassis assembly 140 as illustrated at 401.

The gasket 400 as illustrated in the embodiment of FIG. 4, is comprised of a plurality of segments, all of which are referenced as 405 for ease of understanding. The segmentation of the gasket is related to the amount of EMC control desired. In this regard, narrower or wider strips can be used for each segment 405 to selectively reduce or increase the amount of segments 405 that as a whole comprise gasket 400. A combination of widths can also be used such that some segments 405 are wider than others on the gasket 400. The shape and topography of each segment, however, is closely similar and/or identical despite the width differences in all conditions.

In conclusion of the discussion relating to topography and placement of the gasket, the focus can now be turned back to the illustration of FIG. 5 once again.

FIGS. 5 provides a cross sectional depiction of one of the gasket 400. It should be noted, that since a cross sectional view is provided, however, the gasket 400 as a whole is not visible and only the shape of a single strip 405 is visible. Since all such segments 405, however, are nearly identical in this embodiment and the gasket 400 is provided of a plurality of such strips, discussing the topography of a single segment 405 of the gasket 400 also reveals the topography of the gasket 400 as a whole.

In the illustration of FIG. 5, the chassis 500 is separately illustrated from chassis assembly 140. The chassis 500 may be the entire assembly or a separate element of it. In this embodiment, chassis assembly is illustrated having a protruding element 550 on one side 551. The chassis 500 and the protruding element 505 are preferably fabricated of sheet metal during a single fabrication process. In the embodiment of FIGS. 1 through 4, the chassis 500 is the lock strip 140.

Gasket segment 405 is fabricated of a thin sheet of a conductive material, referenced as 505. In a preferred embodiment the gasket 405 is fabricated out of a thin sheet of metal, such as copper. The thin sheet of material 505 has opposing ends respectively referenced as 501 and 502 and top and bottom surfaces 503 and 504 respectively.

One of the ends 501 of the thin sheet of material (505) forming the gasket section 405 is disposed over the chassis 500 and adhesively bonded (510) to its top side 503. The thin sheet of material 505 is then looped around and secured to the chassis at its opposing end 502 by the use of the protruding element 550 as illustrated in such a manner that it provides facility of compression. The length of the strip 505 along with the percentage of strip 505 that is adhesively bonded to the chassis 505 determines the flexibility of the gasket 400 as a whole. In the illustration of FIG. 5, the arrangement that is shown provides a desired spring like quality for the gasket 400 to enhance facility of compression.

It should be noted that in a preferred embodiment, the gasket is made out of a single sheet transversally segmented, for example by creating slits selectively preferably such that the opposing ends of the gasket/material are not segmented (and still connected) and the gasket can be put in place as a single units. The slits, once the gasket is secured, form individual loops that independently enhance compression of the gasket. In such an embodiment, the portion that is being marked for adhesive bonding and the end disposed under the protruding element 550, for example, have not slits cut out on them.

The protruding element 550 serves multiple functions. The more obvious purpose of the protruding element 550 is to hold the gasket securely at one end and also allow the gasket to maintain its ability to compress. A less obvious purpose is that since the protruding element 550 is preferably made of the same rigid material that forms the chassis 500, it provides support to the thin gasket material such that gasket is not easily torn, damaged or displaced.

The number of the protruding elements provided can also be selectively adjusted to provide more protection if desired. In a functional regard, it is not necessary to have more that a few protruding element for the entire gasket. In such a respect, it would only be necessary to provide a protruding element for every few strip 405. The few protruding element will hold the gasket 400 securely, but if more secure fastening is desired, the number of elements 550 as discussed above can be increased.

The illustration of FIG. 5 only provides for one embodiment of the present invention and other embodiment are possible as per workings of the present invention. For example the manner of securing the first end of the gasket 400 by means of adhesive bonding is only one example as known to those skilled in the art and other similar methods can be used.

FIG. 6 provides a perspective view of the gasket 500 as illustrated. The embodiment of FIG. 6 reflects embodiment of FIGS. 5. The unitary nature of the gasket 400 is more visible in this embodiment. Whether adhesively bonded or retained, when one end is first secured to the chassis, the other end is also well retained by the protrusions in the chassis. In one embodiment of the invention, as visibly shown in FIG. 6, the protrusions have clip like structures that are punched out of chassis sheet metal.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

1. (canceled)

2. An apparatus for providing an electromagnetic seal in electrical enclosure of a device comprising:
an electromagnetic gasket formed of a thin conductive material, having a first end and an opposing end;
a conductive chassis disposed in an electrical enclosure and having protrusions for securing at least one end of said gasket;
said other end of the gasket also being secured to said chassis in a manner to provide facility of compression; and
said gasket being adhesively bonded to said chassis at said other end.

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. An apparatus for providing an electromagnetic seal in electrical enclosure of a device; comprising:
a metal electromagnetic gasket having a first end and an opposing end;
said gasket being formed of a thin metal and having transversal segmentations to facilitate compression;
a metal having a plurality of protrusions such that one end of said gasket can be secured to said chassis via said protrusions;
said other end of said gasket being secured to said chassis by adhesive bonding in a manner that said gasket provides facility of compression.

16. The apparatus of claim 15, wherein said gasket is fabricated of metal or metal compounds.

17. The apparatus of claim 16, wherein said protrusions are on the same parallel plane.

18. A method for providing an electromagnetic seal in electrical enclosure of a device; comprising:
disposing an electromagnetic gasket having a first end and an opposing end over a metal chassis of an electrical device having a plurality of protrusions;
securing said gasket to said plurality of protrusions on one end and adhesively bonding said gasket to said chassis on an opposing end such that said gasket provides facility of compression.

19. The method of claim 18, wherein said gasket is segmented transversely except on said securing ends.

20. The method of claim 18, wherein said protrusions and said chassis are fabricated in a single processing step.
